(19) United States
(12) Patent Application Publication
(10) Pub. No.: US 2008/0224324 A1
(43) Pub. Date: Sep. 18, 2008

(54) SEMICONDUCTOR DEVICE AND METHOD OF MANUFACTURING THE SAME

(75) Inventors: Yumi Kawada, Kanagawa (JP); Satoshi Kaneko, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, Kanagawa (JP)

(21) Appl. No.: 12/045,748

(22) Filed: Mar. 11, 2008

(30) Foreign Application Priority Data
Mar. 12, 2007 (JP) 2007-061996

(51) Int. Cl. H01L 23/52; H01L 21/00

(52) U.S. Cl. 257/778; 438/108; 257/E21.001; 257/E23.141

(57) ABSTRACT

A semiconductor device of one embodiment has a substrate, a semiconductor chip mounted over the substrate by flip-chip bonding, and a semiconductor chip provided over the semiconductor chip, wherein a space resides between the substrate and the semiconductor chip.

This application is based on Japanese patent application No. 2007-061996 the content of which is incorporated hereinto by reference.

### BACKGROUND

1. Technical Field

The present invention relates to a semiconductor device, and a method of fabricating the same.

2. Related Art

In recent mobile communication technology, it has become a common practice to transmit or acquire information using a readily-portable downsized equipment. There has been a still growing demand on the down-sizing, seeking for higher portability. Accordingly, a demand for further down-sizing has arisen also for semiconductor devices used as the components therefor.

However, for the case where the components are mounted linearly or in a two-dimensional manner as shown in FIG. 4A, the maximum number of mountable components may largely be restricted by the area of substrate, minimum pitch of electrodes or the like. A general solution therefor is to mount the components in a three-dimensional manner, in other words in a stacked manner, as shown in FIG. 4B.

In FIG. 4A, two semiconductor chips 102, 104 are mounted in a linear manner. The individual semiconductor chips 102, 104 are connected to electrodes 106 on a substrate (not shown) through bonding wires 108. In this case, of course an area not smaller than the total area of the semiconductor chip 102 and the semiconductor chip 104 is necessary for the mounting.

Alternatively in FIG. 4B, two semiconductor chips 102, 104 are mounted in a three-dimensional manner. More specifically, the semiconductor chip 102 is stacked on the semiconductor chip 104. The semiconductor chip 102 is connected to the electrodes 106 through the bonding wires 108. On the other hand, the semiconductor chip 104 is mounted on the substrate through bumps 110 by flip-chip bonding. The area for mounting on the substrate may be shrunk in this way.

With advancement in transmission speed and realization of mobile communication including transmission of detailed movie images, there is another demand on coping with increase in data capacity. However, frequency bands having conventionally been used are almost exhausted, so that there is an increasing trend of using higher frequency bands. The semiconductor devices are, therefore, requested to cope with higher frequencies.

FIG. 5 is a sectional view showing a semiconductor device described in Japanese Laid-Open Patent Publication No. 2002-237566. On a substrate 202, a semiconductor chip 204 is mounted by flip-chip bonding through projected electrodes 206. On the semiconductor chip 204, a semiconductor chip 208 is provided while placing a die-bonding material 210 in between. The semiconductor chip 208 is electrically connected with the substrate 202 through bonding wires 212. An encapsulation resin 214 is formed so as to cover the semiconductor chips 204, 208. The encapsulation resin 214 is filled also in the region between the substrate 202 and the semiconductor chip 204.

Preceding technical literatures relevant to the present invention other than Japanese Laid-Open Patent Publication No. 2002-237566 include Published Japanese Translation of PCT International Publication for Patent Application No. 2005-505939, and Japanese Laid-Open Patent Publication No. 2006-261485.

The semiconductor device shown in FIG. 5 has an encapsulation resin 214 filled in the region between the substrate 202 and the semiconductor chip 204. The encapsulation resin 214 is, however, causative of increase in parasitic capacitance in this region. The parasitic capacitance undesirably degrades high-frequency characteristics of the semiconductor device.

### SUMMARY

According to the present invention, there is provided a semiconductor device which includes a substrate; a first semiconductor chip mounted over the substrate by flip-chip bonding; and a second semiconductor chip provided over the first semiconductor chip; wherein a space resides between the substrate and the first semiconductor chip.

In this semiconductor device, a space is provided in a region between the substrate and the first semiconductor chip. By virtue of this configuration, the parasitic capacitance may be reduced as compared with the case where the region is filled with an encapsulation resin or the like.

According to the present invention, there is also provided a method of manufacturing a semiconductor device which includes mounting a first semiconductor chip on a substrate by flip-chip bonding; covering a space between the substrate and the first semiconductor chip with a resin sheet; and providing a second semiconductor chip on the first semiconductor chip.

In the method of manufacturing, the space between the substrate and the first semiconductor chip is covered by a resin sheet. By the method, a semiconductor device having a space in a region between the substrate and the first semiconductor chip may be obtained. In thus-configured semiconductor device, the parasitic capacitance may be reduced as compared with the case where the region is filled with an encapsulation resin or the like.

According to the present invention, a semiconductor device successfully reduced in the parasitic capacitance between the substrate and the semiconductor chip, and a method of fabricating such semiconductor device, may be realized.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a sectional view showing one embodiment of the semiconductor device of the present invention;

FIGS. 2A to 3B are sectional views showing process steps of manufacturing the semiconductor device of the present invention;

FIGS. 4A and 4B are plan views showing conventional semiconductor devices; and

FIG. 5 is a sectional view showing the conventional semiconductor device.

### DETAILED DESCRIPTION

The invention will now be described herein with reference to an illustrative embodiment. Those skilled in the art will recognize that many alternative embodiments can be accomplished using the teachings of the present invention and that the invention is not limited to the embodiment illustrated for explanatory purposes.

Paragraphs below will detail preferable embodiments of the present invention, referring to the attached drawings. It is to be noted that any identical constituents will be given with the same reference numerals in the drawings, and explanation therefor will not be repeated.

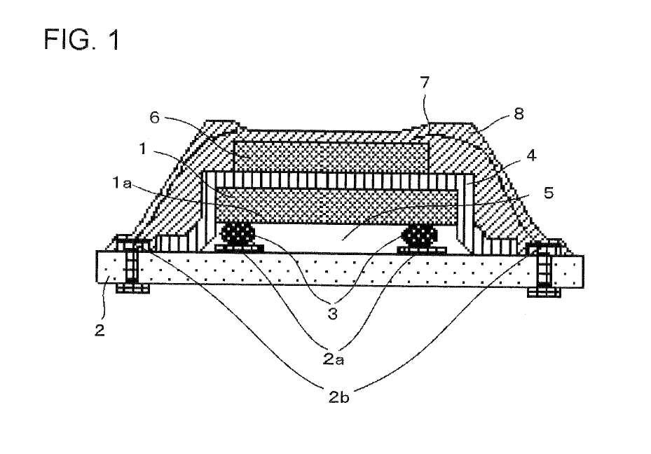

FIG. 1 is a sectional view showing one embodiment of the semiconductor device of the present invention. The semiconductor device has a substrate 2, a semiconductor chip 1 (first semiconductor chip) mounted over the substrate 2 by flip-chip bonding, and a semiconductor chip 6 (second semiconductor chip) provided over the semiconductor chip 1. A space 5 resides between the substrate 2 and the semiconductor chip 1. In other words, the region between the substrate 2 and the semiconductor chip 1 has a hollow structure.

A resin sheet 4 is provided so as to surround the space 5. The resin sheet 4 is provided as being extended from the back surface of the semiconductor chip 1 onto the substrate 2. The semiconductor chip 6 is provided over the semiconductor chip 1 while placing the resin sheet 4 in between. A material composing the resin sheet 4 herein is an epoxy resin, for example. Thickness of the resin sheet 4 is 120 μm, for example. In view of ensuring a sufficient level of strength for realizing the above-described hollow structure, thickness of the resin sheet 4 is preferably 100 μm or above. A thickness of 100 μm or above may facilitate handling of the resin sheet 4, and may make the resin sheet 4 less likely to break. On the contrary, too small thickness of the resin sheet 4 may make it more likely to break due to contact with the corner portions of the semiconductor chip 1, when the sheet is placed on the semiconductor chip 1.

The semiconductor chip 1 is disposed over the substrate 2 in a face-down manner, that is, while directing the circuit plane la downward. The semiconductor chip 1 is connected through bumps 3 to electrodes 2a on the substrate 2. On the other hand, the semiconductor chip 6 is fixed on the back surface of the semiconductor chip 1 using the resin sheet 4. The semiconductor chip 6 is connected to the electrodes 2b on the substrate 2 through the bonding wires 7.

Over the substrate 2, an encapsulation resin 8 is formed so as to cover the semiconductor chip 1 and the semiconductor chip 6. The encapsulation resin 8 is not provided in the space between the substrate 2 and the semiconductor chip 1. In other words, the region is isolated by the resin sheet 4 from the encapsulation resin 8.

The semiconductor device of this embodiment may be applicable, for example, to turn-over switch adaptive to multi-band operation for mobile phones. In this case, the semiconductor chip 1 is typically a semiconductor chip containing a GaAs substrate having switching ICs formed therein. On the other hand, the semiconductor chip 6 is typically a semiconductor chip containing a Si substrate having, as formed therein, step-up ICs for driving the above-described switching ICs.

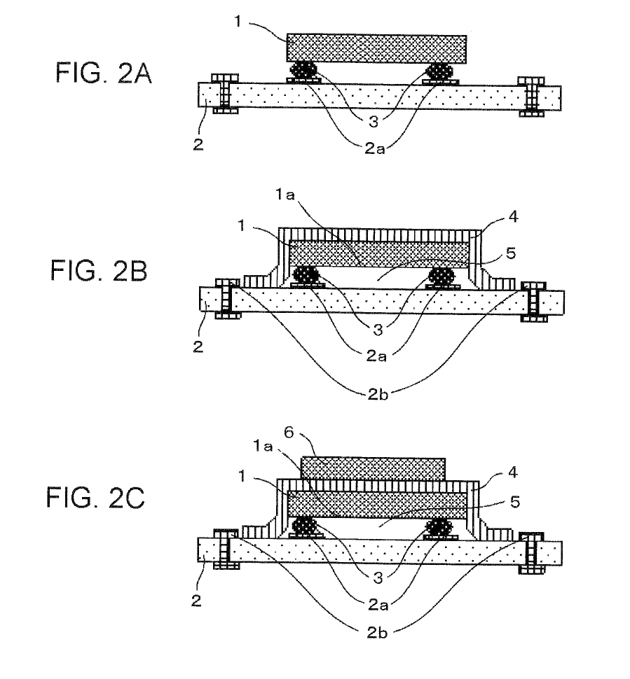

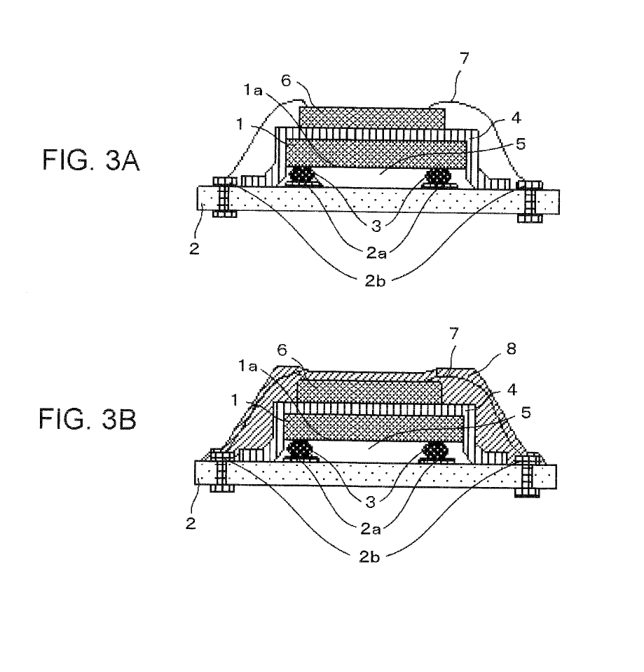

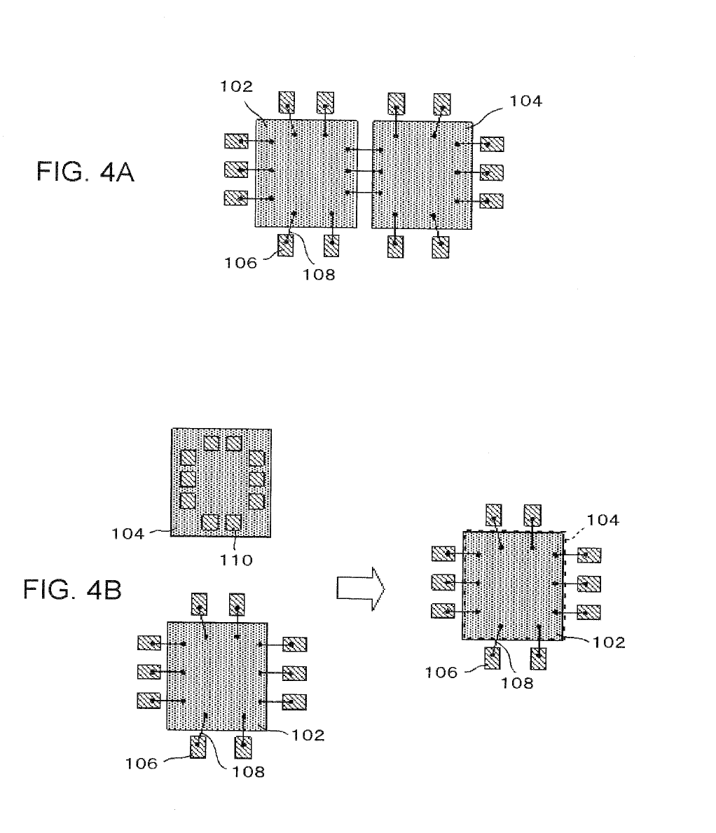

Referring now to FIG. 2A to FIG. 3B, an exemplary method of manufacturing the semiconductor device shown in FIG. 1 will be explained as one embodiment of the method of manufacturing a semiconductor device of the present invention. First, on the substrate 2, a semiconductor chip 1 is mounted by flip-chip bonding (FIG. 2A).

Next, the resin sheet 4 is provided as being extended from the back surface of the semiconductor chip 1 onto the substrate 2, to thereby cover the space 5 between the substrate 2 and the semiconductor chip 1 (FIG. 2B). Thickness and material of the resin sheet 4 herein are selected so as to ensure a sufficient space 5 between the semiconductor chip 1 and the substrate 2. In this embodiment, an uncured resin sheet (remained in the B stage) is used as the resin sheet 4.

Next, on the semiconductor chip 1, the semiconductor chip 6 is put while placing the resin sheet 4 in between (FIG. 2C). The semiconductor chip 6 and the substrate 2 are then electrically connected through the bonding wires 7 (FIG. 3A). Next, the semiconductor chips 1, 6 are covered with an encapsulation resin, while keeping the space remained between the substrate 2 and the semiconductor chip 1 (FIG. 3B). By this process, also the uncured resin sheet 4, the bonding wires 7 and the electrodes 2b are covered with the encapsulation resin 8. For the resin encapsulation in this process, encapsulation using a resin sheet, encapsulation using a liquid resin, or encapsulation using a transfer molding resin may be adoptable. Thereafter, the resin sheet 4 and the encapsulation resin 8 are cured at the same time. By these processes, the semiconductor device shown in FIG. 1 may be obtained.

Effects of this embodiment will be explained. In this embodiment, a space is provided in the area between the substrate 2 and the semiconductor chip 1. By virtue of this configuration, the parasitic capacitance may be reduced as compared with the case where the region is filled with the encapsulation resin or the like. As a consequence, a semiconductor device excellent in the high-frequency characteristics may be realized.

Moreover, area for mounting on the substrate 2 is successfully reduced by mounting two semiconductor chips 1, 6 in a stacked manner.

The space 5 between the substrate 2 and the semiconductor chip 1 is covered with the resin sheet 4, before the encapsulation resin 8 is formed. By this process, the encapsulation resin 8 may be prevented from flowing into the space 5 in the process of resin encapsulation. If the encapsulation resin 8 should enter the space 5, a large parasitic capacitance may be produced between the substrate 2 and the semiconductor chip 1, which is enough to degrade the high-frequency characteristics of the semiconductor device.

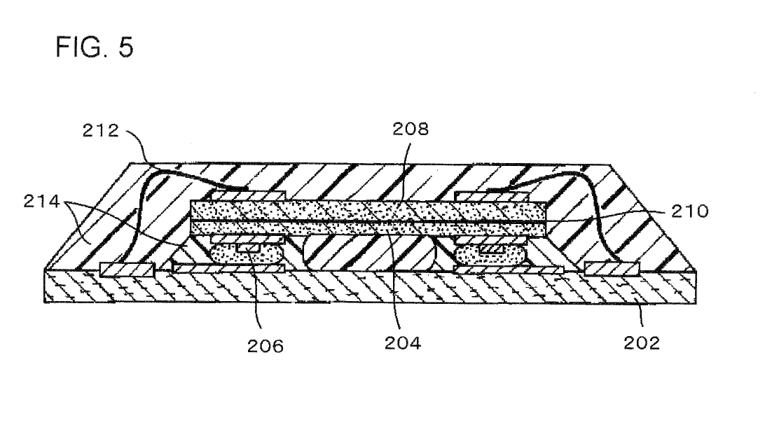

Moreover, because the space 5 is covered with the resin sheet 4, the bonding wires 7 may be prevented from being brought into contact with the bumps 3 or the electrodes 2a in the process of resin encapsulation. In contrast, in the semiconductor device shown in FIG. 5, the bonding wires 212 may undesirably be brought into contact with the electrical connection portions (portions composed of projected electrode 206 and so forth), unless these electrical connection portions between the substrate 202 and the semiconductor chip 204 are completely covered, in the process of encapsulating the whole device with the resin.

The resin sheet 4 in which the curing reaction proceed only up to the B stage is used when the space 5 is covered with the resin sheet 4. This facilitates handling of the resin sheet 4, because the resin sheet 4 can keep its sheet form. It may therefore be easy to avoid coverage of the electrodes 2b with the resin sheet.

The resin sheet 4 is provided as being extended from the back surface of the semiconductor chip 1 onto the substrate 2. By virtue of this configuration, the resin sheet 4 may be used also as a die bonding material for fixing the semiconductor chip 6 on the semiconductor chip 1. As described in the above, the resin sheet 4 of this embodiment has both functions of preventing the encapsulation resin 8 from flowing into the space 5, and as a die bonding material.

Another possible methods of forming the above-described hollow structure may include a method of filling a side-filling material for preventing invasion of the encapsulation resin, in the vicinity of the semiconductor chip, and a method of using a cap made of ceramic, metal or the like. The former method may, however, allow bleeding of the resin through any gap between the side-filling material and the semiconductor chip. On the other hand, the latter method may increase the area for mounting on the substrate, corresponding to the size of cap. Therefore, from the viewpoint of reducing the area for mounting and ensuring stable characteristics, the method of this embodiment, using the resin sheet, takes an advantage over these methods.

It is apparent that the present invention is not limited to the above embodiment, that may be modified and changed without departing from the scope and spirit of the invention.

What is claimed is:

1. A semiconductor device comprising:
a substrate;
a first semiconductor chip mounted over said substrate by flip-chip bonding; and
a second semiconductor chip provided over said first semiconductor chip;
wherein a space resides between said substrate and said first semiconductor chip.

2. The semiconductor device as claimed in claim 1,
further comprising a resin sheet surrounding said space.

3. The semiconductor device as claimed in claim 2,
wherein said resin sheet is provided as being extended from the back surface of said first semiconductor chip onto said substrate, and
said second semiconductor chip is provided over said first semiconductor chip while placing said resin sheet in between.

4. The semiconductor device as claimed in claim 1,
wherein said second semiconductor chip is electrically connected to said substrate through bonding wires.

5. The semiconductor device as claimed in claim 1,
further comprising an encapsulation resin covering said first and second semiconductor chips.

6. The semiconductor device as claimed in claim 1,
wherein said first semiconductor chip contains a GaAs substrate, and
said second semiconductor chip contains a Si substrate.

7. The semiconductor device as claimed in claim 1,
wherein said first semiconductor chip has switching ICs formed therein, and
said second semiconductor chip has step-up ICs for operating said switching ICs formed therein.

8. A method of manufacturing a semiconductor device comprising:
mounting a first semiconductor chip over a substrate by flip-chip bonding;
covering a space between said substrate and said first semiconductor chip with a resin sheet; and
providing a second semiconductor chip on said first semiconductor chip.

9. The method of manufacturing a semiconductor device as claimed in claim 8,
wherein in said covering the space with said resin sheet, said resin sheet is provided as being extended from the back surface of said first semiconductor chip onto said substrate, and
said second semiconductor chip is provided over said first semiconductor chip while placing said resin sheet in between.

10. The method of manufacturing a semiconductor device as claimed in claim 8,
wherein in said covering said space with said resin sheet, a resin sheet remained in the B stage is used as said resin sheet.

11. The method of manufacturing a semiconductor device as claimed in claim 8,
wherein said providing said second semiconductor chip further contains electrically connecting said second semiconductor chip and said substrate through bonding wires.

12. The method of manufacturing a semiconductor device as claimed in claim 8,
further comprising covering said first and second semiconductor chips with an encapsulation resin.
